(19) United States
(12) Patent Application Publication
(10) Pub. No.: US 2025/0112173 A1
(43) Pub. Date: Apr. 3, 2025

(54) PRE-ASSEMBLY WARPAGE COMPENSATION OF THIN DIE STRUCTURES

(71) Applicant: Intel Corporation, Santa Clara, CA (US)

(72) Inventors: Kimin Jun, Portland, OR (US); Feras Eid, Chandler, AZ (US); Adel Elsherbini, Chandler, AZ (US); Thomas Sounart, Chandler, AZ (US); Yi Shi, Chandler, AZ (US); Wenhao Li, Chandler, AZ (US)

(73) Assignee: Intel Corporation, Santa Clara, CA (US)

(21) Appl. No.: 18/374,577

(22) Filed: Sep. 28, 2023

(51) Int. Cl. H01L 23/00; H01L 23/31

(52) U.S. Cl. CPC H01L 23/562; H01L 23/3121; H01L 24/08; H01L 24/80; H01L 2224/08225; H01L 2224/80895; H01L 2224/80896

(57) ABSTRACT

A surface of an integrated circuit (IC) die structure and a substrate to which the IC die structure is to be bonded include biphilic regions suitable for liquid droplet formation and droplet-based fine alignment of the IC die structure to the substrate. To ensure warpage of the IC die structure does not interfere with droplet-based fine alignment process, an IC die structure of greater thickness is aligned to the substrate and thickness of the IC die structure subsequently reduced. In some embodiments, a back side of the IC die structure is polished back post attachment. In some alternative embodiments, the IC die structure includes sacrificial die-level carrier is removed after fine alignment and/or bonding.

### BACKGROUND

Integrated circuit (IC) die can be assembled with solder attachment techniques where solder features are brought into contact to join dies to a host or base substrate. However, solder assembly techniques are difficult to scale below solder-bonded feature pitches that are in the tens of microns (e.g., 10-25 μm).

IC die may instead be assembled with hybrid bonding techniques where metallic bond sites of an IC die are directly interdiffused with corresponding metallic bond sites of a host or base substrate. Such bonding is referred to as “hybrid” where a bond also forms between dielectric materials adjacent to the metallic bond sites. During a hybrid bonding process, components (e.g., dies) having corresponding bond site structures, are brought together to interface with one another. At room temperature, dielectric material adheres sufficiently to establish an initial bond (e.g., due to Van der Waals forces). A thermal anneal may then fuse complementary metallic bond sites, and also increase the strength of the dielectric material bond interface. Hybrid bonding techniques are scalable well below bonded feature pitches of 1 μm. However, such nanometer pitch assembly techniques rely on nanometer scale (e.g., <500 nm) fine alignment of IC die to the base substrate, which can be time consuming and/or expensive to implement.

Techniques and architectures for hybrid bonding at nanometer scales in high volume manufacturing are therefore commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating assembly methods for thin integrated circuit (IC) die structures, in accordance with some embodiments;

FIGS. 2, 3, 4, 5 and 6 are cross-sectional view of a wafer or panel comprising a plurality of IC die structures as selected blocks of the method illustrated in FIG. 1 are performed, in accordance with some embodiments;

FIG. 7A is a cross-sectional view of a wafer or panel comprising a plurality of base substrate structures, each base substrate structure comprising a biphilic surface structure, in accordance with some embodiments;

FIG. 7B is a plan view of the base component wafer or panel illustrated in FIG. 7A, in accordance with some embodiments;

FIG. 8A is a cross-sectional view of thin IC die structures being coarse aligned and placed on liquid droplets confined in bonding regions, in accordance with some embodiments;

FIG. 8B is a plan view of aligning and placing the thin IC die structures of FIG. 8A, in accordance with some embodiments;

FIG. 9A is a cross-sectional view of a composite structure comprising thin IC die structures hybrid bonded to bonding regions of biphilic structures, in accordance with some embodiments;

FIG. 9B is a plan view of the composite structure shown in FIG. 9A, in accordance with some embodiments;

FIG. 10A is a cross-sectional view of a composite structure comprising thin IC die structures hybrid bonded to bonding regions of biphilic structures, in accordance with some alternative embodiments;

FIG. 10B is a plan view of the composite structure shown in FIG. 10A, in accordance with some embodiments;

FIG. 11 is a cross-sectional view of a composite package structure as selected blocks of the method illustrated in FIG. 1 are performed, in accordance with some embodiments;

FIG. 12 is a cross-sectional view of system comprising a heat sink and a host component assembled with a hybrid bonded composite structure further comprising a thin IC die structure, in accordance with some embodiments;

FIG. 13 illustrates a mobile computing platform and a data server machine employing a multi-chip package, in accordance with some embodiments; and

FIG. 14 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). As another example, a composition that is predominantly a first and second constituent more than half of the composition is the first and second constituents (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As previously noted, hybrid bonding techniques offer advantages in the assembly of IC die structures to other IC die structures or some other host structure, such as a package substrate structure, interposer structure, or the like. In accordance with embodiments herein, an IC die structure may include any monolithic integrated circuit device that provides electrical, compute, memory, or similar functionality. An IC die structure may itself comprise more than one monolithic integrated circuit device. For example, an IC die structure may comprise two vertically stacked IC dies or two coplanar IC dies. IC dies within an IC die structure may be directly bonded to each other or coupled through interconnect features. IC die structures in accordance with embodiments herein may be referred to as “chiplets,” “chiplet dies,” “dice,” “tiles,” or “chips,” for example. While the terms chiplet and IC die or chip may be used interchangeably, a fully functional ASIC is typically considered an IC die or chip while a chiplet or tile would have more limited functionality, for example supplementing one or more other IC chiplets that are to be part of the same multi-chiplet device. A chiplet or tile may, for example, be a wireless radio circuit, microprocessor core, electronic memory circuit, floating point gate array (FPGA), power management and/or power supply circuit, or include a MEMS device.

In the context of hybrid bonding IC die structures, self-alignment assisted assembly (SA3) may facilitate greater die-to-wafer hybrid bonding (D2W HB) throughput by reducing the burden of fine alignment. In some exemplary SA3 processes, bonding regions are incorporated into “biphilic” or “heterogeneous” surface structures on either (or both) an IC die structure or (and) a host structure. Biphilic/heterogeneous surfaces have a high wettability contrast between their distinct regions. As described further herein, a high wettability contrast can be achieved by physical patterning (e.g., creating trenches around the bonding area to confine liquid via the canthotaxis effect), chemical patterning (e.g., depositing hydrophobic coatings to lower surface energy around the bonding area), or combinations of the two (e.g., creating trenches with hydrophobically coated sidewalls surrounding the bonding area).

Within a biphilic surface structure one region has high wettability relative to another region of low wettability. This wettability contrast can improve control of liquid droplet spreading such that a liquid droplet may be confined on a bonding site of either (or both) an IC die structure or (and) a host structure. Surface tension of the droplet acts to passively fine-align the IC die structure as the droplet evaporates, leaving the bonding regions in contact and ready for hybrid bonding. At room temperature, attractive surface forces between the dielectric regions on the IC die structure and a host structure may suffice to temporarily affix the two. A hybrid bond may be subsequently formed through application of pressure and/or elevated temperature to form and/or strengthen bonds between the metal features (e.g., metal pads) dispersed within surrounding dielectric material. Once bonded, the metal features form a composite metal feature that electrically interconnects an IC die structure and a host structure. In some embodiments, however, bonding may be dielectric-dielectric only or metal-metal only (e.g., for thermal applications or some RF applications).

With SA3, a bonder may pick and place an IC die structure upon a host structure in reliance on coarse alignment (e.g., ˜25-50 um) alone, enabling fast assembly. When a liquid droplet is confined to a bonding region between the IC die structure and the host structure, capillary forces and liquid surface tension induce alignment with high positional accuracy (e.g., <200 nm) due to the biphilic or transition structures on mating surfaces of the IC die structure and/or host structure. Such biphilic or heterogenous structures may therefore be more specifically referred to as “self-alignment features” or “SA3 features.”

Regardless of the assembly technique, however, it is desirable to scale IC die thickness for many reasons. However, as IC die substrate (e.g., silicon) thickness is reduced to a level comparable to the thickness of the back-end-of-line interconnect levels monolithically fabricated upon the die substrate (e.g. <50 um), total die warpage increase so significantly that die handling and die bonding becomes very challenging. Furthermore, although embodiments of the present invention are not limited to liquid-based assembly techniques, the inventors have noted that for such techniques the lowest energy state of a droplet surface may not correspond to an ideal alignment condition for IC die structures having significant warpage. Also, warpage within an IC die structure may cause part of the die to contact a surface of the base substrate structure at a point in time when there is still relatively large liquid droplet volume, which may interfere with passive alignment assembly techniques.

Generally, warpage increases with thinner IC die structures. For example, out-of-plane displacement of a surface of an IC die structure comprising a typical silicon die substrate layer may increase by more than two orders of magnitude as thickness of the silicon substrate is reduced from 50 μm to 0.5 μm. Handling and bonding of IC die structures may therefore become more challenging as IC die structure structures are thickness scaled.

As described further below, embodiments herein comprise hybrid bonding of an IC die structure to a host structure. Such bonding may be facilitated by liquid droplet-based fine alignment. However, other bonding alignment techniques or other assembly techniques may also be practiced. In some embodiments, to enable superior alignment performance, the IC die structure is provided (or received) in an initial state having sufficiently low warpage and high planarity of the bonding surface. Wafer-level thinning is then performed to reduce IC die thickness significantly below its initial thickness. This thickness reduction may be performed to any extent desired for z-scaling a bonded composite structure.

While the thin wafer is mechanically supported by a carrier, a backside material layer is then deposited upon the back side of the IC die substrate. The backside material layer is tuned to have a particular stress and a particular thickness suitable for compensating the cumulative strain an IC die will undergo upon singulation from the wafer and separation from the carrier. As further described below, the backside material layer may be uniform to impart a stress that compensates monotonic strain or warpage of an IC die structure. The backside material layer may also be patterned to engineer a more complex stress field that is non-uniform over an IC die structure to compensate strain in an IC die structure that would otherwise have a non-monotonic shape over an area of the die structure.

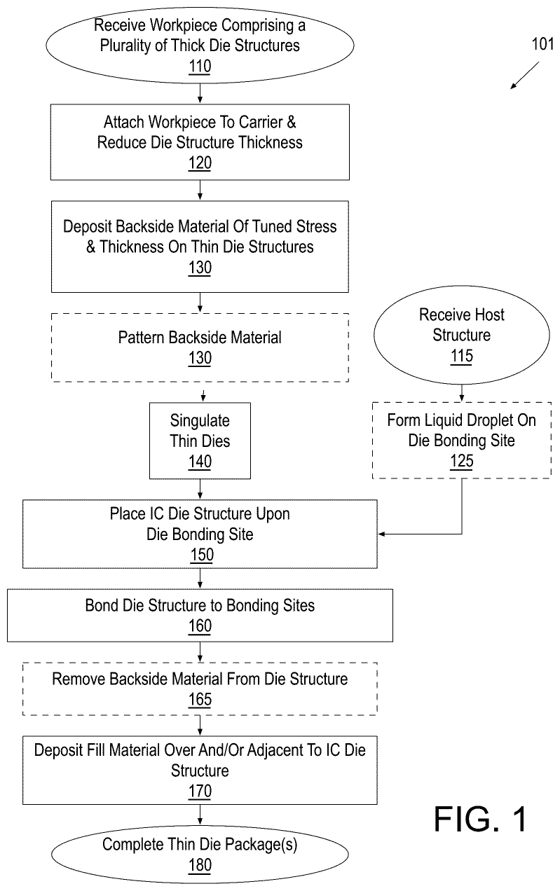

FIG. 1 is a flow diagram illustrating self-alignment assisted assembly methods 101 for thin integrated circuit (IC) die structures, in accordance with some embodiments. In methods 101, IC die structures with a stress compensating backside material layer are of sufficiently low warpage for assembly to a host structure according to one or more SA3 techniques. After they are bonded, the backside material layer may be retained within the assembly or removed as sacrificial. Methods 101 may be practiced, for example, to form one or more of the assemblies described elsewhere herein. Methods 101 are illustrated as including several discrete blocks to ensure clarity of description. However, in practice the number of blocks, and/or order of blocks, may be modified without departing from the principles illustrated by methods 101.

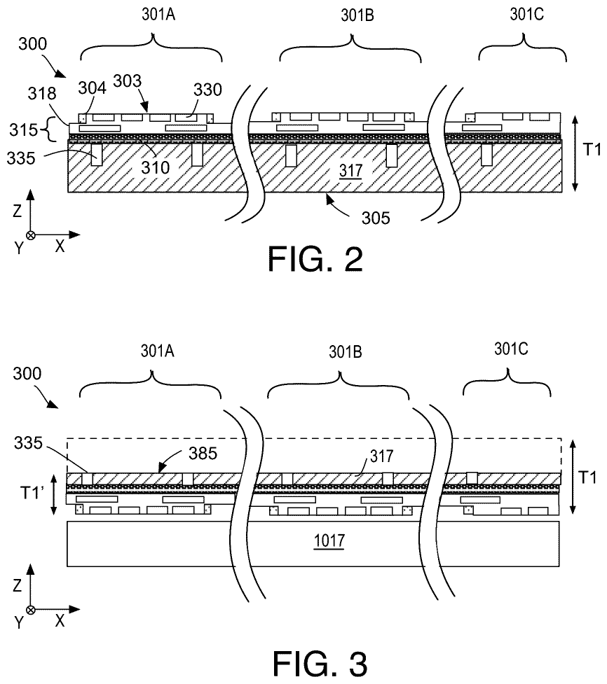

Methods 101 begin at input 110 where thick IC die structures are received. The IC die structures may be portions of any wafer, etc. that is suitable for processing a plurality of IC die structures concurrently. FIG. 2 is a cross-sectional view of a wafer 300 comprising a plurality of aggregated “IC die structures 301A, 301B, 301C. In the illustrated example, each IC die structure 301A-301C comprises one or more biphilic surface structures on a first (e.g., top) side of one or more IC die substrate materials 317. IC die structures 301A-301C include a device layer 310 in contact with IC die substrate material(s) 317, and IC die metallization levels 315 over device layer 310. IC die structures 301A-301C further illustrate an example including optional through substrate vias (TSVs) 335 extending from device layer 310 into IC die substrate material(s) 317.

The chemical composition of IC die substrate material(s) 317 may vary with implementation. In exemplary embodiments IC die substrate material(s) 317 includes a monocrystalline material layer. The monocrystalline material layer may be, for example, predominantly silicon and is advantageously substantially pure silicon. However, the monocrystalline material layer may be of alternative compositions, such as, but not limited to, germanium (Ge), silicon germanium alloys (SiGe), gallium arsenide alloys (GaAs), indium phosphide alloys (InP), gallium nitride alloys (GaN), silicon carbide alloys (SiC), etc.

Device layer 310 comprises active devices (not depicted). In some embodiments, the active devices within device layer 310 are field effect transistors (FETs). The FETs may be of any architecture (e.g., planar, non-planar, single-gate, multi-gate, stacked nanosheet, etc.) and may have a feature pitch of 10-30 nm, for example. Additionally, or in the alternative, device layer 310 may include active devices other than FETs. For example, device layer 310 may include electronic memory structures, spin valves, or the like.

IC die structures 301A-301C comprise IC die metallization levels 315 on a front side of device layer 310. For IC die structures 301A-301C, a bonding region 303 comprises an uppermost one of metallization features 330. Metallization features 330 are embedded in and/or dispersed over a dielectric material 318. Each of metallization features 330 may comprise any metal known to be suitable for direct bonding. At least the uppermost level of metallization features 330 may be predominantly Cu, for example.

Bonding region 303 further comprises dielectric material 318. Dielectric material 318 may have any chemical composition suitable for hybrid bonding. Dielectric material 318 is advantageously an inorganic material, for example comprising at least 20 atomic % of one or more of silicon, oxygen, or nitrogen. In some embodiments, dielectric material 318 is primarily silicon and oxygen (e.g., SiO₂), primarily silicon and nitrogen (e.g., Si₃N₂), or primarily silicon, oxygen and nitrogen (e.g., SiₓO_{y}Nₓ), any of which may further comprise one or more dopants, such as carbon. Inorganic dielectric materials are nevertheless distinct from organic dielectrics (e.g., epoxy resins and phenolic-glasses), which have much higher carbon content and a higher percentage of carbon-hydrogen bonds.

Each IC die structure 301A-301C further comprises a hydrophobic region 304 adjacent to a bonding region 303 providing biphilic or transition structures with a wettability contrast between bonding region 303 of high wettability, and a laterally adjacent peripheral region 304 of low wettability. Although the liquid may vary (polar or non-polar, etc.), in exemplary SA3 embodiments employing water, the bonding region of high wettability is hydrophilic (i.e., inducing a water droplet to have a contact angle of less than 90°). A water droplet will therefore tend to spread out over region 303 as the liquid minimizes its surface energy. The adjacent region 304 of low wettability is hydrophobic (i.e., inducing a water droplet to have a large contact angle of greater than 90°).

Hydrophobic region 304 may comprise any chemical coating or thin film material and/or topographic structure that enhances a hydrophobic boundary adjacent to one or more edges of bonding region 303. In some embodiments, region 304 comprise a self-assembled monolayer (SAM) material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). Other SAM embodiments may comprise disulfides, amines, azoles, amides, imides, pyridine derivatives, cyanoacrylate derivatives or other moieties which include a sulfur atom or a nitrogen atom. SAM reactions typically form monolayer molecules aligned with each other in a uniform manner. Such a molecule may be introduced in the vapor phase and “self-assemble” by forming a highly selective bond at the surface and orientating itself perpendicular to the face of the surface. However, non-SAM based materials or films are also possible. In some embodiments, region 304 is, or includes, a polymer thin film such as a siloxane (e.g., PDMS and derivatives, HMDSO), a silazane (HMDS), a polyolefin (e.g., PP), or a fluorinated polymer (e.g., PTFE, PFPE, PFDA, C₄F₈ plasma polymerized films, etc.). In some advantageous embodiments, regions 204 have a chemical composition with at least ten atomic percent (at. %) carbon or at least ten at. % fluorine.

Region 304 may additionally, or in the alternative, comprise topographic features that increase wettability contrast relative to bonding region 303. A topographic trench within region 304 may, for example, improve wettability contrast between region 304 and bonding region 303. Such a topographic feature can change a liquid droplet's effective contact angle to greater than 90° and thereby alter the surface energy characteristics of the droplet. In some further embodiments, region 304 has significantly higher average surface roughness than bonding regions 303. Region 304 may be roughened with any surface texturing techniques, such as laser surface roughening. Roughened surfaces may have any surface roughness greater than the surface roughness of a bonding region. For example, bonding regions 30 may have a low surface roughness (e.g., <15 nm average roughness for metallization and <1 nm average roughness for dielectric) while region 304 has high surface roughness (e.g., >50 nm average roughness). In some embodiments, the average surface roughness of region 304 is at least twice the average surface roughness of the surface of a bonding region and may be five, ten, or twenty times that of a bonding region. As used herein, average roughness (or center line average) is as described in ASME B46.1. Average roughness is the arithmetic average of the absolute values of profile height deviations from a mean line that is recorded for an evaluation length. Average roughness may be measured, for example, with a profilometer comprising a stylus that is traversed over a surface, or by atomic force microscopy (AFM). For region 304 having a longitudinal length in a first dimension (e.g., coincident with x-axis), average roughness may be measured over a distance roughly 60-70% of the longitudinal length while remaining at about a centerline of a transverse width of region 304 that is in a dimension substantially orthogonal to the first dimension (e.g., coincident with y-axis).

In wafer form, IC die structures 301A-301C have an initial thickness T1, which may vary with implementation. In some embodiments, thickness T1 is significantly over 50 μm, and may be 100-500 μm, or more. Within such a thickness range, warpage of IC die structures 301A-301C can be minimal (e.g., with an out of plane displacement of less than 2 μm) over an area or footprint of bonding region 303.

Returning to FIG. 1, methods 101 continue at block 120 where the workpiece comprising the IC die structures is attached to a front-side carrier and the thickness of the IC die structures is reduced by removing some amount of the IC die substrate material. At block 120, the substrate material may be removed, for example with a chemical mechanical planarization (CMP) system or any other suitable grinder and/or polisher, etc. The thinning process(es) may reduce a thickness of an IC die structure to the limit of workpiece total thickness variation (TTV). In some embodiments, the thickness of an IC die substrate (e.g., monocrystalline silicon layer) is reduced by at least 30%, and advantageously by 50-80%.

FIG. 3 illustrates a thinning of IC die structures 301A-301C from backside 385. A front side of wafer 300 is attached to any suitable carrier material(s) 1017, such as a glass, quartz, sapphire, or silicon handling wafer. The IC die structures are reduced from thickness T1 to a lesser thickness T1′. Thinning of IC die structures 301A-301C exposes TSVs 335, rendering the IC die structures ready for fabrication of backside interconnect features. The difference between IC die structure thicknesses T1 and T1′ may vary as a function of the initial thickness of IC die substrate material 317. In some embodiments where IC die thickness T1 is over 50 μm, thickness T1′ is less than 50 μm. Hence, for some embodiments where IC die substrate material 317 has an initial thickness T1 over 50 μm, IC die substrate material 317 may be thinned by 30-50%, or more so that thickness T1′ is less than 50 μm. In some specific embodiments, IC die substrate material 317 may be thinned to less than 10 μm (e.g., 0.5-5 μm).

Returning to FIG. 1, methods 101 continue at block 130 where one or more material layers are formed on, or in, the backside of the thinned IC die structures. The material layers formed on, or in, the backside surface of the IC die substrate compensate stress/strain present within the IC die structures. The backside material layer(s) may, for example counterbalance stress induced by other films within the IC die structure and/or improve the IC die structure's stress resilience. The backside material layer(s) may therefore be considered stress-tuning material to counter what is referred to herein as “in-situ” bow, which is bow that would occur if a thinned IC die structure lacking the backside material layer(s) was to be separated from the carrier. In some embodiments, the backside material layer(s) induce a mitigating stress that reduces strain experienced by the IC die structures to a level below a threshold that corresponds to a room temperature (e.g., 25-30° C.) state that is sufficiently flat for bonding to be substantially unimpeded by IC die warpage.

To counter stress in IC die structures, the backside material layer may be formed under conditions that impart compressive or tensile stress within the backside material (e.g., at room temperature). If in-situ bow of an IC die structure is positive, a backside material layer under compressive stress may reduce positive in-situ bow. Likewise, a backside material under tensile stress at ambient room temperature may reduce negative in-situ bow.

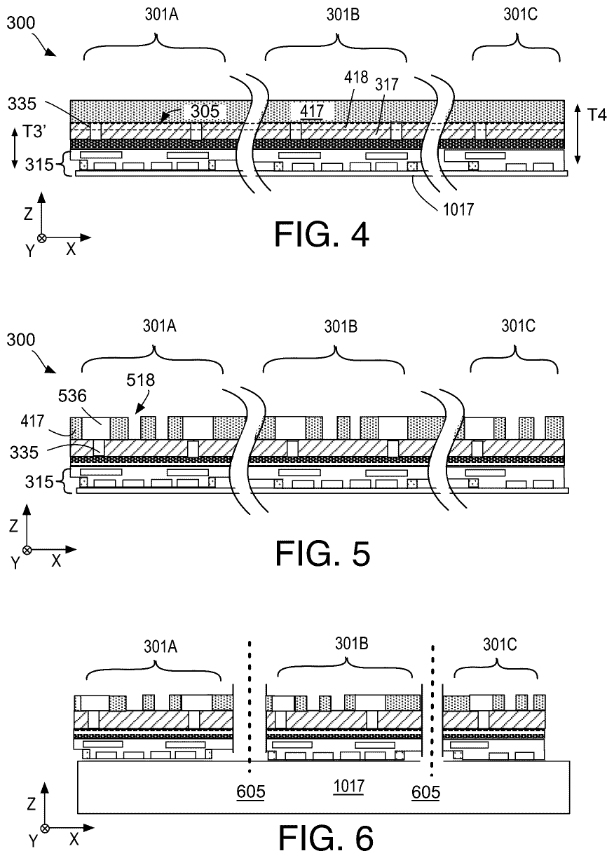

In the examples illustrated in FIG. 4, a backside material layer 417 comprises a material of a different chemical composition than that of IC die substrate materials 317. In the illustrated example, backside material layer 417 is in direct contact with one of the IC die substrate materials 317 (e.g., silicon). However, one or more intervening material layers may be between IC die substrate materials 317 and backside material layer 417. In some embodiments, backside material layer 417 is amorphous silicon. In other embodiments, backside material layer 417 is a chemical compound of silicon, such as a silicon oxide (predominantly silicon and oxygen), silicon nitride (predominantly silicon and nitrogen), silicon carbide (predominantly silicon and carbon), silicon oxy-nitride (predominantly silicon, oxygen and nitrogen), silicon-oxy carbide (predominantly silicon, oxygen and carbon), silicon carbo-nitride (predominantly silicon, carbon and nitrogen), or silicon-oxy-carbo-nitride (predominantly silicon, oxygen, carbon and nitrogen). A backside material layer of silicon or of a compound of predominantly silicon and one or more of these other constituents, may be deposited, for example, by chemical vapor deposition (CVD), plasma enhanced CVD (PECVD), or physical vapor deposition (PVD). These deposition techniques are operated with parameters that cause backside material layer 417 to be either tensilely or compressively stressed.

In other embodiments, backside material layer 417 is metal or a chemical compound of a metal. For example, backside material layer 417 maybe predominantly any of, Ti, W, Ta, Mo, or Co. These metals may be sputter deposited, for example, in substantially pure or alloyed forms. These metals adhere well to crystalline silicon substrate surfaces, and can be deposited at various parameters (e.g., pressures and magnetron powers) to achieve a predetermined film stress suitable for counterbalancing stress in the IC die structures 301A-301C. Chemical compounds of metals, such as metal oxides and metal nitrides may also be suitable for counterbalancing stress in IC die structures 301A-301C. Exemplary metal compounds include aluminum oxide (predominantly aluminum and oxygen), aluminum nitride (predominantly aluminum and nitrogen), titanium oxide (predominantly titanium and oxygen), or titanium nitride (predominantly titanium and nitrogen).

In some other embodiments, the backside material layer comprises a partial thickness of the IC die crystalline substrate material, which has been altered to enhance internal stress fields. For such embodiments, the backside material layer may be substantially co-planar with TSVs 335, as further denoted in FIG. 4 by the dashed thickness 418 of substrate material(s) 317. For such embodiments, one or more impurities are introduced into backside thickness 418, for example through an ion implantation process. A concentration of impurities within thickness 418 is substantially higher (e.g., at least 3 orders of magnitude higher) than that of any impurities within a remainder of the crystalline substrate material. The higher impurity concentration within thickness 418 can impart significant stress in the lattice of the crystalline substrate material. The impurities may be blanket implanted over an entirety of substrate material(s) 317, substantially as illustrated for substrate thickness 418. Alternatively, an implant mask may be employed to localize the implant and form the backside material layer only within a subset of regions within substrate material(s) 317. Although the impurity may vary, in some examples where substrate material(s) 317 include crystalline silicon, one or more of germanium, boron, antimony, arsenic or phosphorus are implanted into the silicon.

Depending on the embodiment and level of stress being compensated, the thickness of backside material layer 417 (or modified substrate thickness 418) may vary from around 100 nm to 5 μm, or more. Notably, multiple backside material layer embodiments may be combined, for example with the deposition of multiple backside material layers, or by combining substrate material alteration and the deposition of a backside material layer substantially as illustrated in FIG. 4. Such combinations may impart a larger magnitude of stress or impart stress that is otherwise better at compensating the in-situ bow of the IC die structure through the cumulative effects of each embodiment.

Returning to FIG. 1, methods 101 optionally continue at block 130 where the backside material layer is patterned, for example with an etch process that forms recesses or openings through at least a partial thickness of the backside material layer. As denoted by the used of dashed line, block 130 is optional and may be practiced for a variety of reasons, for example to further tune the stress field, and/or to accommodate backside electrical connections, and/or to fabricate a structure suitable for assembling the IC die structure to a host structure in a backside-to-host (e.g., back-to-face) orientation.

Block 130 may entail any photolithographic mask patterning process and etch process suitable for the composition of the backside material layer. The etch process may remove only a partial thickness, forming recesses in the backside material layer, or may remove the full thickness of backside material to expose the IC die substrate material. In the example illustrated in FIG. 5, recesses 518 have been etched through the full thickness of backside material layer 417. As further illustrated, backside metallization features 536 have been built up within recesses in backside material layer 417 that expose through vias 335. Backside metallization is most compatible with dielectric backside material layer embodiments (e.g., silicon dioxide or silicon nitride, etc.). However, alternative implementations may be practiced for metallic backside material layer embodiments, for example with additional patterning of backside material layer 417 to avoid electrical shorts.

Backside metallization features 536 may have any composition with exemplary embodiments comprising predominantly Cu. For embodiments where an IC die structure lacks through vias, backside metallization features 536 need not be formed, and recesses 518 may all be left open to free space as a means of further tuning stress fields of an IC die structure. For IC die structures 301A-301C that do include through vias 335, a single patterning process, metallization process (e.g., Cu plating) and planarization process may be practiced to metallize all recesses 518 (even those that are for stress tuning and do not intersect a through via 335). Alternatively, a first patterning of backside material layer 417, a metallization process and planarization process may be followed with a second patterning of backside material layer 417 to arrive at the illustrated structure where some recesses 518 are open to free space (e.g., for stress tuning) and others have been metallized.

Returning to FIG. 1, methods 101 continue at block 140 with any additional backside processing of the stress-compensated thin die structures followed by singulation of the IC die structures so they may be removed from the carrier. Additional backside processing may entail the application of additional dielectric material layers (e.g., organic materials) and/or metallization levels built up upon the backside IC die surface, for example with any suitable semi-additive process (SAP). The backside processing may also entail formation of one or more biphilic structures to form one or more backside bonding regions substantially as described above for bonding region 203 and adjacent hydrophobic region 204. Depending on the composition of the stress-compensating backside material layer, backside biphilic structures may be fabricated directly within the stress-compensating backside material layer or may be built up over the stress-compensating backside material layer. FIG. 6 illustrates one example where the stress compensated IC die structures 301A-301C have been singulated along saw lines 605 and are ready to be picked from carrier 1017.

Returning to FIG. 1, a host structure is received at a second input 115 to methods 101. A host structure may be a portion of any wafer, panel, or strip, etc. that is suitable for the formation of bonding site features that are to be directly bonded, or otherwise interconnected, with one or more IC die structures. The bonding site features are formed within a bonding region of the host structure. In some embodiments, the bonding region is integrated into one or more biphilic surfaces that are suitable for SA3 assembly.

For embodiments where the host structure received at input 115 is a base (package) substrate structure, the IC die structure received at input 110 is to be assembled with the substrate structure received at input 115. In other embodiments where the host structure received at input 115 is an IC die structure, the IC die structure recited at input 110 is to be assembled with the host IC die structure received at input 115.

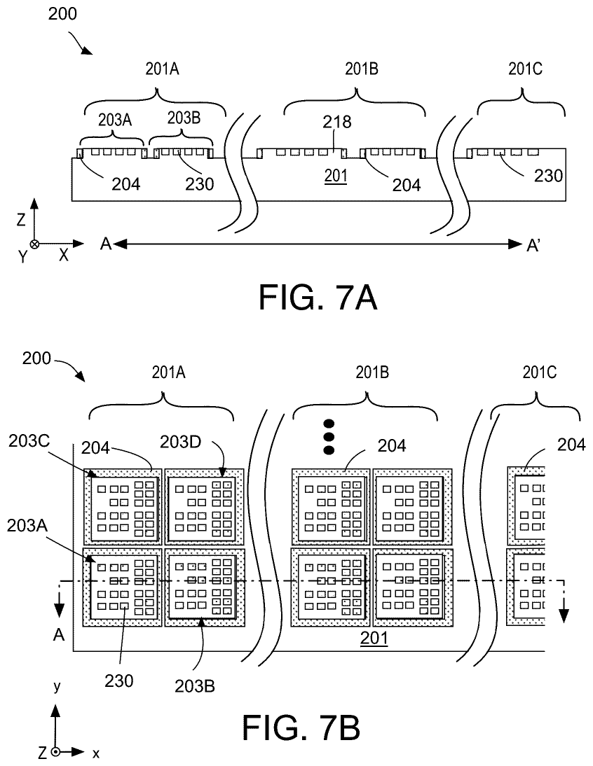

FIG. 7A is a cross-sectional view of a host structure 200, in accordance with some embodiments. FIG. 7B is a plan view of host structure 200, in accordance with some further embodiments. The cross-sectional plane A-A′ illustrated in FIG. 7A is demarked by a dot-dashed A-A′ line in FIG. 2B.

Host structure 200 comprises one or more or one or more substrate materials 201. Substrate materials 201 may vary according to implementation. In some embodiments where host structure 200 is a package substrate structure, or package interposer structure, substrate materials 201 may include one or more structural material layers, such as semiconductor materials (e.g., monocrystalline), sapphire, or glass. Substrate materials 201 may include any of those found in an integrated circuit wafer, such as semiconductor materials (e.g., silicon, germanium, GaN, GaAs, InP, InGaAS, etc), on-die interconnect layers (e.g., copper, aluminum, tantalum, other metals), and on-die dielectrics (e.g., silicon dioxide, carbon-doped silicon dioxide, silicon nitride, silicon carbide, etc.). For glass embodiments, the structural material may be predominantly silica (e.g., silicon and oxygen) and may further include one or more elements such as hydrogen, carbon and/or metals, such as, but not limited to copper, silver, gold, aluminum, beryllium, magnesium, calcium, strontium barium, or radium. Additional dopants (e.g., boron, phosphorus) may also be present in the structural material (e.g., borosilicate glass, etc.).

Substrate materials 201 may also include one or more levels of metallization features 230. Metallization features 230 may be embedded, for example, within a dielectric material. The dielectric material may have been built up on one or more side of a structural material layer, for example. Structural material layers may be retained or ultimately discarded so that substrate materials 201 may comprise only dielectric material and embedded routing metallization features 230. Dielectric material may be an organic dielectric, such as, an epoxy resin, phenolic-glass, or a resinous film such as the GX-series films commercially available from Ajinomoto Fine-Techno Co., Inc.(ABF). Package dielectric material may comprise epoxy resins (e.g., an acrylate of novolac such as epoxy phenol novolacs (EPN) or epoxy cresol novolacs (ECN)). In other examples, package dielectric material includes aliphatic epoxy resin, which may be monofunctional (e.g., dodecanol glycidyl ether), difunctional (butanediol diglycidyl ether), or have higher functionality (e.g., trimethylolpropane triglycidyl ether).

Host structure 200 may also comprise an inorganic dielectric material (e.g., comprising at least 20 atomic % of one or more of silicon, oxygen, or nitrogen). In some embodiments, the inorganic dielectric material is primarily silicon and oxygen (e.g., SiO₂), primarily silicon and nitrogen (e.g., Si₃N₂), or primarily silicon, oxygen and nitrogen (e.g., SiₓO_{y}Nₓ). An inorganic dielectric material may further comprise one or more dopants, such as carbon. Inorganic dielectric materials are nevertheless distinct from organic dielectrics (e.g., epoxy resins and phenolic-glasses), which have much higher carbon content and a higher percentage of carbon-hydrogen bonds.

Substrate materials 201 may also include one or more IC die structures (not depicted). In some embodiments where host structure 200 is a package substrate or interposer, an IC die structure is embedded within dielectric material. In other embodiments, host structure 200 is an IC die structure. Such IC die structures may be fully functional ASICs or may be chiplets or tiles of more limited functionality to supplement one or more other IC die structures that are to be part of the same multi-chip device. For embodiments where host structure 200 is an IC die structure, substrate materials 201 may include any of those materials typical of monolithically fabricated IC dies, such as, but not limited to, a device material layer and/or a silicon (e.g., monocrystalline) layer, inorganic dielectric materials (e.g., comprising at least 20 atomic % of one or more of silicon, oxygen, or nitrogen), and metallization features 230.

Metallization features 230 may comprise one or more metals or metal alloys. In some embodiments, metallization features 230 includes a barrier material (not depicted), which may line an interface with a surrounding dielectric material. The barrier material may be Ti, TiN, Ta, or TaN, for example. In some further embodiments, metallization features 230 comprise a fill metal over the barrier material. Exemplary fill metals comprise predominantly Cu.

In some exemplary embodiments, host structure 200 further comprise a biphilic surface structure corresponding to a complementary surface structure on IC die structures. As shown in FIG. 7A and 7B, each bonding region 203A, 203B, 203C and 203D comprises an uppermost one of metallization features 230. Bonding regions 203A-203D may metallization features 230 of any pitch compatible with an IC die structure that is to be assembled upon host structure 200.

Host structure 200 further comprises a region 204 adjacent to a bonding region 203A-203D. Regions 204 may include any of the properties or characteristics discussed elsewhere herein for region 204 of an IC die structure. In some embodiments, bonding region 203A-203D and adjacent regions 204 are fabricated according to any of the techniques discussed above for corresponding regions of IC die structures.

As further illustrated in FIG. 7B, region 204 substantially surrounds a perimeter of each bonding region 203A-203D. Region 204 may be a single continuous material and/or structure with a hydrophobic surface. Alternatively, region 204 may comprise multiple discontinuous hydrophobic material and/or structural segments delineating a perimeter about two or more edges of each bonding region 203A-203D.

Returning to FIG. 1, for those embodiments where a liquid-based fine alignment and assembly process is practiced, a liquid droplet may be formed on each bonding region of the host structure at block 125. Any techniques suitable for the liquid, such as vapor condensation or direct liquid dispense (i.e., printing) may be practiced at block 125 as embodiments are not limited in this respect. In some exemplary embodiments, a water droplet is dispensed at block 125. However, alternative polar (e.g., alcohols) or non-polar (e.g., solvents) liquids may be dispensed at block 125 depending on the nature of the host structure's wettability contrast.

A liquid droplet may be formed on IC die structures that are to be bonded to the host structure either in addition to the droplet formed on the bonding regions of the host structure, or as an alternative to the droplet formed on the host structure. Methods 101 then continue at block 150 where the stress-compensated IC die structure singulated at block 140 is placed over a bonding region of the host structure.

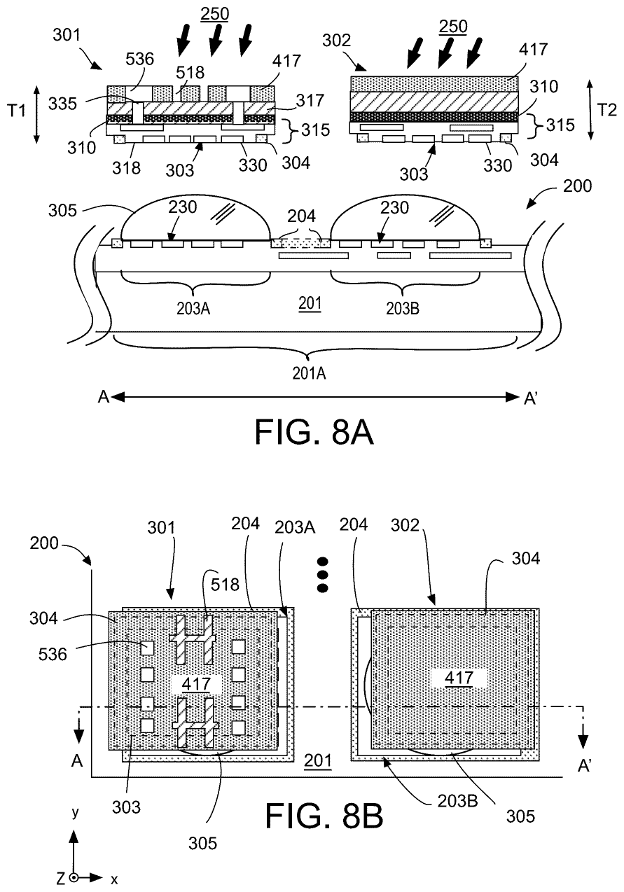

FIG. 8A is a cross-sectional view of stress-compensated IC die structures 301, 302 undergoing an initial coarse alignment 250 to host structure 200. IC die structure 302 illustrates an embodiment where backside material layer 417 is substantially continuous and of substantially uniform thickness over any entire area of the IC die structure. IC die structures 301 and 302 may therefore include completely different ASICs or chiplets with wholly distinct functionality that are heterogeneously integrated with their co-assembly upon host structure 200. Originating from a different source wafer, backside material layer 417 on IC die structure 302 may be substantially the same as backside material layer 417 on IC die structure 301, or the two backside material layers 417 may be of a different composition and/or thickness (e.g., to compensate different stress fields particular to the different IC die structures).

In the illustrated example, IC die structures 301, 302 are placed upon liquid droplets 305 confined to bonding regions 203A, 203B, in accordance with some embodiments. Coarse alignment 250 may be performed, for example, with pick-and-place equipment. Such equipment may be capable of positional accuracy within 25-50 μm in each of the x-dimension and y-dimension, for example. FIG. 8B is a plan view of coarse alignment 250 and placement of IC die structures 301, 302, in accordance with some embodiments. Some alignment error is illustrated in FIG. 8B with liquid (e.g., water) droplet 305 to correct the misalignment during a passive fine alignment (e.g., via capillary forces, etc.) phase until the droplet evaporates. In exemplary embodiments, the fine alignment is advantageously to within 200 nm in each of the x-dimension and orthogonal y-dimension. FIG. 3B further illustrates recesses 518 as having a polygonal shape associated with a stress field solution that best compensates a non-monotonic warpage function.

In some exemplary embodiments, individual ones of metallization features 330 correspond to individual ones of metallization features 230, both having a feature pitch in the range of 100 nm to 10 μm, for example. The biphilic surface structures on host structure 200 and the biphilic surface structures on IC die structures 301, 302 may be substantially the same (as illustrated) or they may differ compositionally and/or structurally.

Returning to FIG. 1, methods 101 continue at block 160, where the IC die structure is bonded to the host structure. Any bonding technique, such as any hybrid bonding technique may be practiced at block 160. In some exemplary embodiments that rely on liquid-based alignment, a liquid droplet between an IC die structure and the host structure is evaporated at block 160, bringing the IC die structure bonding region in direct contact with the base substrate bonding region. The IC die structure may then be bonded to the host structure.

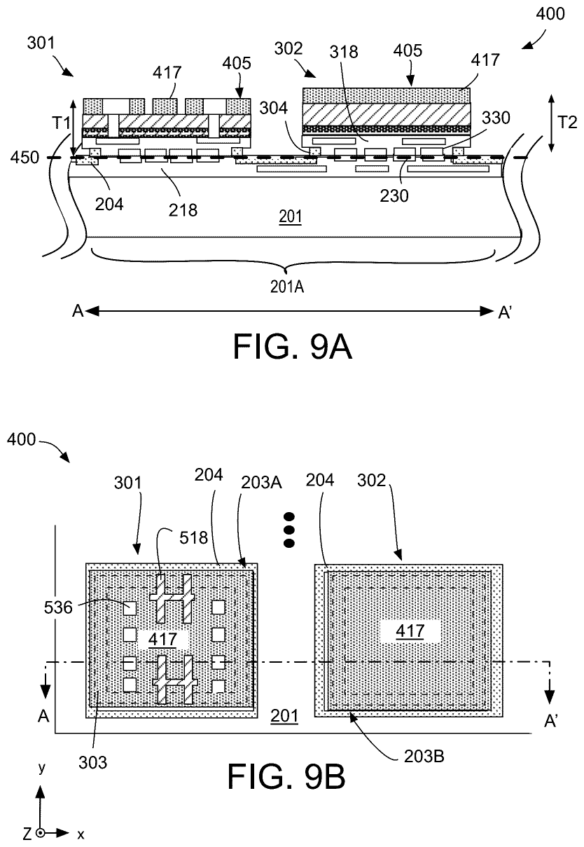

FIG. 9A illustrates an exemplary hybrid bonded composite structure 400 where front faces of IC die structures 301 and 302 are now in direct contact with host structure 201A along bonding interface 450, denoted by a thick dashed line. As shown, metal features 230 are in direct contact with at least a portion of corresponding ones of metal features 330. Dielectric material 218 of base substrate structure 201A is likewise in direct contact with dielectric material 318 of IC die structures 301 and 302. An extent of lateral offset between metal features 230 and 330 along bonding interface 450 is indicative of fine alignment tolerances.

Individual ones of regions 204 on base substrate structure 201A are co-located with corresponding ones of regions 304 on IC die structures 301 and 302. Regions 204 may also be in direct contact with regions 304 along bonding interface 450, although they may not interdiffuse or meld to form a unified composite structure even after a thermos and/or compression bonding process. As both IC die structures 301 and 302 are bonded along a substantially planar bonding interface 450, IC die backside surface 405 may not be co-planar if there is a difference between die structure thicknesses T1 and T2.

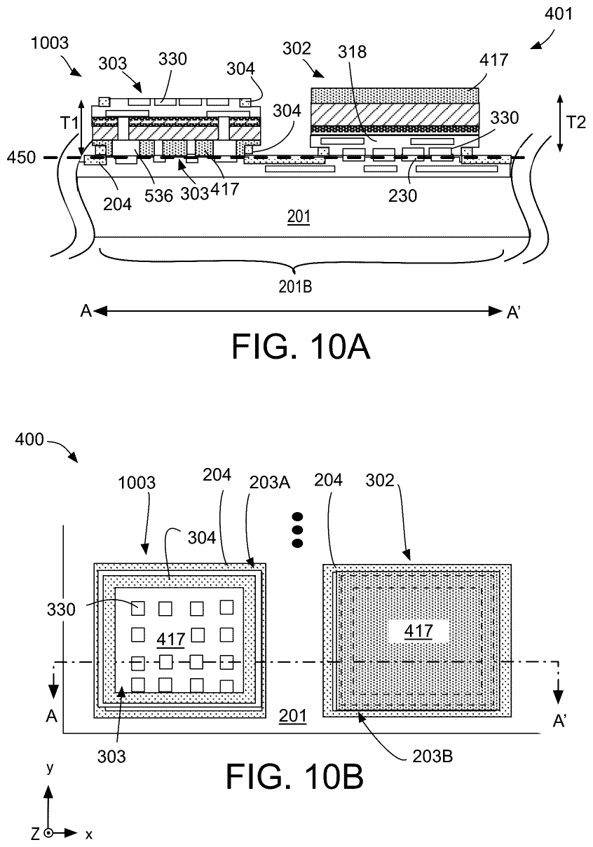

FIG. 10A is a cross-sectional view of a composite structure 401 in accordance with some alternative embodiments where a back side of an IC die structure 1003 is directly bonded to host structure 201A. In this example, the front side of IC die structure 302 is directly bonded to host structure 201A, substantially as described elsewhere herein. For IC die structure 1003, a biphilic structure including metallization features 536 has been fabricated into backside material layer 417. Backside material layer, which for this embodiment is advantageously a dielectric, such as silicon dioxide, not only compensates stress in IC die structure 1003, but is further patterned to include a trench around IC die bonding region 303 to facilitate passive alignment. A hydrophobic region 304 is within the trench improve wettability contrast, for example substantially as described elsewhere herein.

FIG. 10B is a plan view of the composite structure shown in FIG. 10A, in accordance with some embodiments. As shown, a front side of IC die structure 1003 includes another bonding region 303 surrounded by another hydrophobic region 304. An additional IC die structure may therefore be subsequently bonded to the front side of IC die structure 1003, forming an IC die structure stack. Alternatively, the front side of IC die structure 1003 may be otherwise interconnected to other IC die structures within composite structure 401, or external to composite structure 401, for example with solder bumps, etc.

Returning to FIG. 1, methods 101 may optionally proceed to block 165 where backside material may be removed from the IC die structures as sacrificial. Block 165 is shown in dashed line as optional because in some embodiments the backside material is retained as a permanent architectural feature of an IC die structure. However, since the IC die structures are now bonded to the host structure, stress compensation provided by the backside material may no longer be needed and so may be optionally stripped off. Any etch process selective to the composition of the backside material layer may be practiced at block 165.

Methods 101 continue at block 170 where a fill material is deposited over the bonded IC die structure, and over portions of the host structure that is not occluded by an IC die structure. The fill material deposited at block 150 is advantageously a dielectric material. The fill material may be an inorganic dielectric material or an organic dielectric material, for example any of those previously described. In exemplary embodiments the fill material is deposited to a thickness at least equal to the thickness of the IC die structure. The fill material may be deposited by any technique known to be suitable for the chosen composition and thickness of material. In some embodiments, a dielectric fill material may be applied with a spin-on or spray-on process and subsequently cured. In other embodiments, a dielectric fill material may be deposited with a chemical vapor deposition (CVD) process. In still other embodiments, a dielectric fill material may be deposited at block 170 with a molding process. Depending on the deposition process, the dielectric fill material may be planar along a length spanning the IC die structure and extending beyond an edge of the IC die structure. The fill material may be planarized, for example with a chemical mechanical planarization (CMP) system or any other suitable grinder and/or polisher.

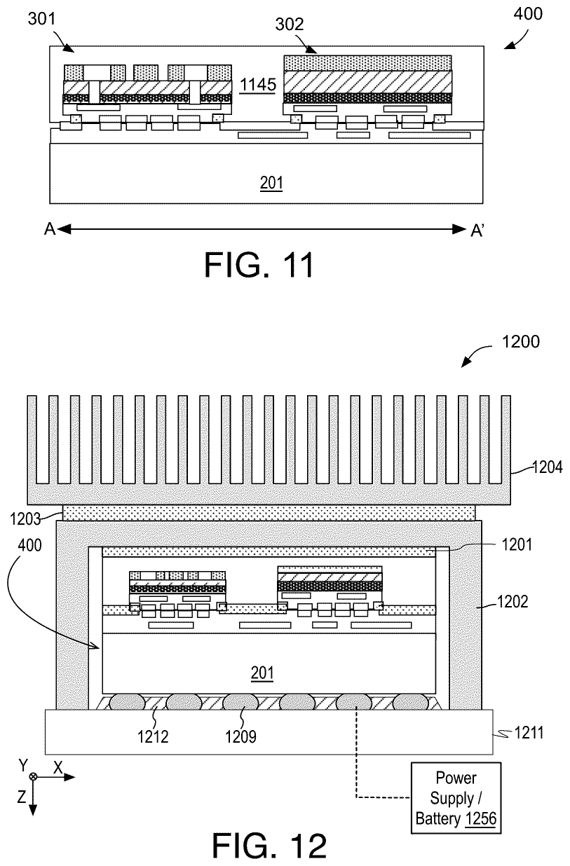

In the example illustrated in FIG. 11, composite structure 400 further includes a dielectric material 1145 over IC die structures 301, 302. Dielectric material 1145 also substantially backfills a gap between adjacent edge sidewalls of IC die structures 301, 302. In some embodiments, dielectric material 1145 is one or more of any of the inorganic dielectric compositions previously described. In some other embodiments, dielectric material 1145 is one or more of any of the organic dielectric compositions previously described. As illustrated, dielectric material 1145 is substantially planarized across IC die structures 301, 302. Such planarization may be attributable to a dielectric deposition process and/or a post-deposition polishing or CMP process.

FIG. 12 is a cross-sectional view of system 1200 comprising a heat sink 1204 and a host component substrate 1211 assembled with a hybrid bonded composite structure 1600 further comprising a thin IC die, in accordance with some embodiments. Although illustrated with an integration of composite structure 400 (FIG. 9A), system 1200 may similarly comprise composite structure 401 (FIG. 10A). System 1200 may include any number of such composite structures mounted to host substrate 1211 via interconnects 1209, which are optionally embedded in an underfill material 1212. Substrate 1211 may be a cored or coreless package substrate, interposer, or board (such as a motherboard), for example.

System 1200 further includes a power supply 1256 coupled to one or more of substrate 1211 (i.e., a board, package substrate, or interposer), composite structure 1600, and/or other components of system 1200. Power supply 1256 may include a battery, voltage converter, power supply circuitry, or the like. System 1200 further includes a thermal interface material (TIM) 1201 over composite structure 1600. TIM 1201 may include any suitable thermal interface material. System 1200 further includes an integrated heat spreader (IHS) and/or lid 1202 in contact with TIM 1201 and extends over composite structure 1600. System 1200 further includes another TIM 1203 in contact with a top surface of IHS 1202. TIM 1203 may include any suitable thermal interface material and may be of the same composition as TIM 1001, or not. System 1200 includes a heat sink 1204 (e.g., an exemplary heat dissipation device or thermal solution) in contact with TIM 1203. System 1200 may be further integrated into a computer, such as a mobile device or server, for example.

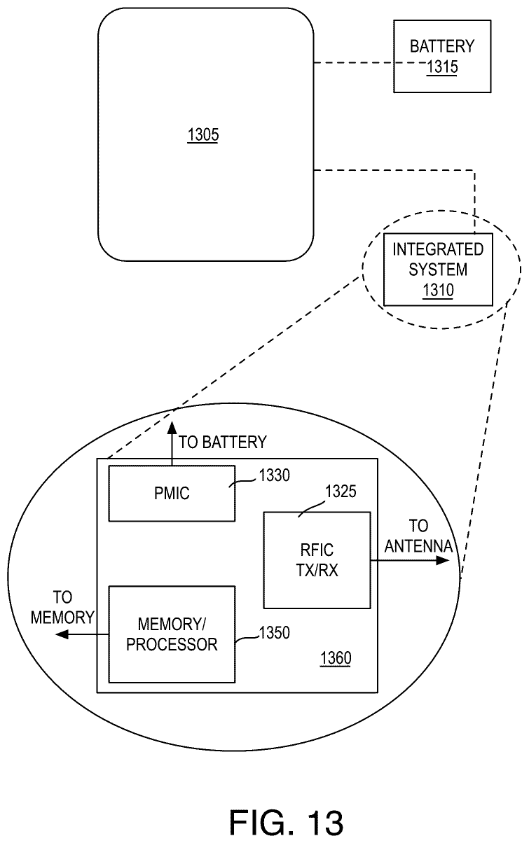

FIG. 13 illustrates an exemplary computer platform 1305 including a composite structure including a stress-compensated bonded IC die comprising a backside material layer comprising a compensatory stress field. Platform 1305 may be a mobile computing platform and/or a data server machine, for example. A server machine may be any commercial server, for example, including any number of high-performance computing platforms disposed within a rack and networked together for electronic data processing. Platform 1305 may be any portable device configured for each of electronic data display, electronic data processing, wireless electronic data transmission, or the like. Platform 1305 may include a chip-level or package-level integrated system 1310, and a battery 1315. In some examples, the disclosed systems may be implemented in a disaggregated sub-system 1360.

Sub-system 1360 may include memory circuitry and/or processor circuitry 1350 (e.g., RAM, a microprocessor, a multi-core microprocessor, graphics processor, etc.), a power management integrated circuit (PMIC) 1330, and a radio frequency integrated circuit (RFIC) 1325 (e.g., including a wideband RF transmitter and/or receiver (TX/RX)). As shown, one or more IC dice, such as memory circuitry and/or processor circuitry 1350 may be co-packaged and/or co-assembled within a composite structure including a stress-compensated IC die having biphilic structures proximately to a hybrid bond interface, for example as described herein.

In some embodiments, RFIC 1325 includes a digital baseband and an analog front end module further comprising a power amplifier on a transmit path and a low noise amplifier on a receive path). Functionally, PMIC 1330 may perform battery power regulation, DC-to-DC conversion, etc., and so has an input coupled to battery 1315, and an output providing a current supply to other functional modules. As further illustrated in FIG. 13, in the exemplary embodiment, RFIC 1325 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1350 may provide memory functionality, high level control, data processing and the like for sub-system 1360.

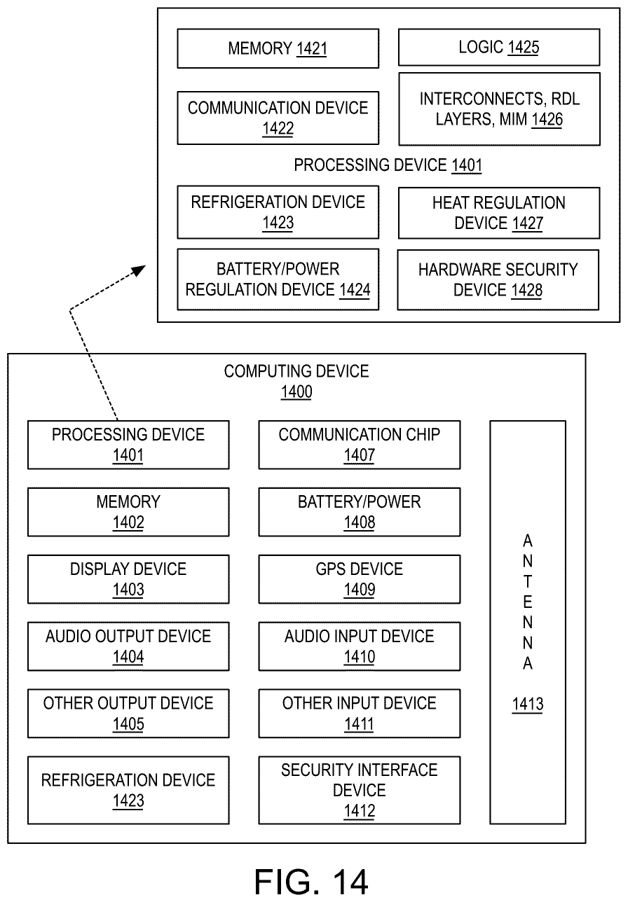

FIG. 14 is a block diagram of a cryogenically cooled computing device 1400 in accordance with some embodiments. For example, one or more components of computing device 1400 may include any of the devices or structures discussed elsewhere herein. A number of components are illustrated in FIG. 14 as included in computing device 1400, but any one or more of these components may be omitted or duplicated, as suitable for the application. In some embodiments, some of the components included in computing device 1400 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1400 may not include one or more of the components illustrated in FIG. 14, but computing device 1400 may include interface circuitry for coupling to the one or more components. For example, computing device 1400 may not include a display device 1403, but may include display device interface circuitry (e.g., a connector and driver circuitry) to which display device 1403 may be coupled.

Computing device 1400 may include a processing device 1401 (e.g., one or more processing devices). As used herein, the term processing device or processor indicates a device that processes electronic data from registers and/or memory to transform that electronic data into other electronic data that may be stored in registers and/or memory. Processing device 1401 may include a memory 1421, a communication device 1422, a refrigeration/active cooling device 1423, a battery/power regulation device 1424, logic 1425, interconnects 1426, a heat regulation device 1427, and a hardware security device 1428.

Processing device 1401 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1401 may include a memory 1402, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing 1401 shares a package with memory 1402. This memory may be used as cache memory and may include embedded dynamic random-access memory (eDRAM) or spin transfer torque magnetic random-access memory (STT-M RAM).

Computing device 1400 may include a heat regulation/refrigeration device 1423. Heat regulation/refrigeration device 1423 may maintain processing device 1401 (and/or other components of computing device 1400) at a predetermined low temperature during operation. This predetermined low temperature may be any temperature discussed elsewhere herein.

In some embodiments, computing device 1400 may include a communication chip 1407 (e.g., one or more communication chips). For example, the communication chip 1407 may be configured for managing wireless communications for the transfer of data to and from computing device 1400. The term “wireless” and its derivatives may be used to describe circuits, devices, systems, methods, techniques, communications channels, etc., that may communicate data through the use of modulated electromagnetic radiation through a nonsolid medium.

Communication chip 1407 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1407 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1407 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1407 may operate in accordance with other wireless protocols in other embodiments. Computing device 1400 may include an antenna 1413 to facilitate wireless communications and/or to receive other wireless communications (such as AM or FM radio transmissions).

In some embodiments, communication chip 1407 may manage wired communications, such as electrical, optical, or any other suitable communication protocols (e.g., the Ethernet). As noted above, communication chip 1407 may include multiple communication chips. For instance, a first communication chip 1407 may be dedicated to shorter-range wireless communications such as Wi-Fi or Bluetooth, and a second communication chip 1407 may be dedicated to longer-range wireless communications such as GPS, EDGE, GPRS, CDMA, WiMAX, LTE, EV-DO, or others. In some embodiments, a first communication chip 1407 may be dedicated to wireless communications, and a second communication chip 1407 may be dedicated to wired communications.

Computing device 1400 may include battery/power circuitry 1408. Battery/power circuitry 1408 may include one or more energy storage devices (e.g., batteries or capacitors) and/or circuitry for coupling components of computing device 1400 to an energy source separate from computing device 1400 (e.g., AC line power).

Computing device 1400 may include a display device 1403 (or corresponding interface circuitry, as discussed above). Display device 1403 may include any visual indicators, such as a heads-up display, a computer monitor, a projector, a touchscreen display, a liquid crystal display (LCD), a light-emitting diode display, or a flat panel display, for example.

Computing device 1400 may include an audio output device 1404 (or corresponding interface circuitry, as discussed above). Audio output device 1404 may include any device that generates an audible indicator, such as speakers, headsets, or earbuds, for example.

Computing device 1400 may include an audio input device 1410 (or corresponding interface circuitry, as discussed above). Audio input device 1410 may include any device that generates a signal representative of a sound, such as microphones, microphone arrays, or digital instruments (e.g., instruments having a musical instrument digital interface (MIDI) output).

Computing device 1400 may include a global positioning system (GPS) device 1409 (or corresponding interface circuitry, as discussed above). GPS device 1409 may be in communication with a satellite-based system and may receive a location of computing device 1400, as known in the art.

Computing device 1400 may include another output device 1405 (or corresponding interface circuitry, as discussed above). Examples include an audio codec, a video codec, a printer, a wired or wireless transmitter for providing information to other devices, or an additional storage device.

Computing device 1400 may include another input device 1411 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1400 may include a security interface device 1412. Security interface device 1412 may include any device that provides security measures for computing device 1400 such as intrusion detection, biometric validation, security encode or decode, managing access lists, malware detection, or spyware detection.

Computing device 1400, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In first examples, an apparatus comprises an integrated circuit (IC) die structure of a thickness no more than 50 μm. A first side of the IC die structure has a first region comprising one or more first metal features and an inorganic dielectric material, and a second, adjacent, region comprising a layer of material with a composition of at least ten atomic percent carbon or at least ten atomic percent fluorine. A second side of the IC die structure comprises a backside material layer over a crystalline die substrate. The backside material layer is impurity-doped crystalline silicon, amorphous silicon, a compound of silicon, a compound of a metal, or a meta. The apparatus comprises a substrate in direct contact with at least the first region of the IC die structure. The substrate has a second region comprising one or more second metal features and an inorganic dielectric material. The apparatus comprises a dielectric material over the IC die structure and over a portion of the substrate beyond an edge of the IC die structure.

In second examples, for any of the first examples the backside material layer is the compound of silicon or the compound of metal and wherein the compound further comprises oxygen, nitrogen, or carbon.

In third examples, for any of the second examples the backside material layer is the compound of metal and wherein the metal comprises Al, Ti or Ta.

In fourth examples, for any of the third examples the backside material layer is predominantly aluminum and oxygen, predominantly aluminum and nitrogen, predominantly titanium and nitrogen, or predominantly tantalum and nitrogen.

In fifth examples, for any of the second examples the backside material layer is predominantly silicon and oxygen, predominantly silicon and nitrogen, or predominantly silicon and carbon.

In sixth examples, for any of the first examples the backside material layer is metal and wherein the metal is predominantly Ti, Ta, W, Mo or Co.

In seventh examples, for any of the first examples a plurality of recesses extends through at least a partial thickness of the backside material layer.

In eighth examples, for any of the first through seventh examples the backside material layer has a thickness of 100 nm-5 μm.

In ninth examples, for any of the first through eighth examples the backside material layer is crystalline silicon comprising an impurity at a higher concentration than that of the crystalline silicon die substrate, and wherein the impurity is one or more of germanium, boron, antimony, arsenic or phosphorus.

In tenth examples, for any of the ninth examples the backside material layer comprises the impurity only within a subset of regions spanning an area of the second side of the IC die structure.

In eleventh examples, an apparatus comprises a first integrated circuit (IC) die structure of a thickness no more than 50 μm. A front side of the first IC die structure has a first region comprising one or more first metal features and an inorganic dielectric material. A back side of the first IC die structure comprises a backside material layer over a crystalline silicon die substrate. The backside material layer is impurity-doped crystalline silicon, amorphous silicon, a compound of silicon, a compound of a metal, or a metal. The apparatus comprises a second IC die structure of a thickness no more than 50 μm. A back side of the IC die structure has a second region comprising one or more second metal features and an inorganic dielectric material. A back side of the second IC die structure further comprises a backside material layer over a crystalline die substrate and substantially coplanar with the second metal features, wherein the backside material layer comprises predominantly silicon and at least one of oxygen, nitrogen, or carbon. The apparatus comprises a substrate in direct contact with the first region of the first IC die structure and the second region of the second IC die structure. The substrate has a third region comprising one or more third metal features in contact with the first metal features and the substrate has a fourth region comprising one or more fourth metal features in contact with the second metal features. The apparatus comprises a dielectric material over the first and second IC die structures and over a portion of the substrate beyond between the first and second IC die structures.

In twelfth examples, for any of the eleventh examples a front side of the second IC die structure is coupled to the second metal features by a conductive via extending through the crystalline die substrate.

In thirteenth examples, for any of the eleventh through twelfth examples the backside material layer comprises predominantly silicon and oxygen.

In fourteenth examples, for any of the eleventh through thirteenth examples a plurality of recesses extends through at least a partial thickness of the backside material layer.

In fifteenth examples, for any of the eleventh through fourteenth examples the backside material layer has a thickness of 100 nm-5 μm.

In sixteenth examples a method comprises receiving a wafer of integrated circuit (IC) die structures. The wafer is of a first thickness, and the IC die structure has a first region comprising one or more first metal features and an inorganic dielectric material. The method comprises thinning the wafer by removing a thickness of a crystalline substrate of the IC die structures. The method comprises forming a backside material over the crystalline substrate after thinning the wafer. The backside material comprises impurity-doped crystalline silicon, amorphous silicon, a compound of silicon, a compound of a metal, or a metal. The method comprises receiving a host structure with a second region comprising one or more second metal features and an inorganic dielectric material. The method comprises bonding the first region to the second region. The bonding comprises contacting the first metal features with at least a portion of corresponding ones of the second metal features.

In seventeenth examples, for any of the sixteenth examples the method comprises aligning the IC die structure to the host structure based on a wettability contrast between the first region and the second region.

In eighteenth examples, for any of the sixteenth through seventeenth examples the method further comprises patterning the backside material.

In nineteenth examples, for any of the sixteenth through eighteenth examples the method comprises removing the backside material from the crystalline substrate after bonding the first region to the second region.

In twentieth examples, for any of the sixteenth through nineteenth examples the method comprises thinning the wafer reduces the IC die structure to a total thickness of less than 50 μm.

It will be recognized that principles of the disclosure are not limited to the embodiments so described, but instead can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
an integrated circuit (IC) die structure of a thickness no more than 50 μm, wherein:
a first side of the IC die structure has a first region comprising one or more first metal features and an inorganic dielectric material, and a second, adjacent, region comprising a layer of material with a composition of at least ten atomic percent carbon or at least ten atomic percent fluorine;
a second side of the IC die structure comprises a backside material layer over a crystalline die substrate, wherein the backside material layer is impurity-doped crystalline silicon, amorphous silicon, a compound of silicon, a compound of a metal, or a metal;
a substrate in direct contact with at least the first region of the IC die structure, wherein the substrate has a second region comprising one or more second metal features and an inorganic dielectric material; and
a dielectric material over the IC die structure and over a portion of the substrate beyond an edge of the IC die structure.

2. The apparatus of claim 1, wherein the backside material layer is the compound of silicon or the compound of metal and wherein the compound further comprises oxygen, nitrogen, or carbon.

3. The apparatus of claim 2, wherein the backside material layer is the compound of metal and wherein the metal comprises Al, Ti or Ta.

4. The apparatus of claim 3, wherein the backside material layer is predominantly aluminum and oxygen, predominantly aluminum and nitrogen, predominantly titanium and nitrogen, or predominantly tantalum and nitrogen.

5. The apparatus of claim 2, wherein the backside material layer is predominantly silicon and oxygen, predominantly silicon and nitrogen, or predominantly silicon and carbon.

6. The apparatus of claim 1, wherein the backside material layer is metal and wherein the metal is predominantly Ti, Ta, W, Mo or Co.

7. The apparatus of claim 1, wherein a plurality of recesses extends through at least a partial thickness of the backside material layer.

8. The apparatus of claim 1, wherein the backside material layer has a thickness of 100 nm-5 μm.

9. The apparatus of claim 8, wherein the backside material layer is crystalline silicon comprising an impurity at a higher concentration than that of the crystalline silicon die substrate, and wherein the impurity is one or more of germanium, boron, antimony, arsenic or phosphorus.

10. The apparatus of claim 9, wherein the backside material layer comprises the impurity only within a subset of regions spanning an area of the second side of the IC die structure.

11. An apparatus comprising:
a first integrated circuit (IC) die structure of a thickness no more than 50 μm, wherein:
a front side of the first IC die structure has a first region comprising one or more first metal features and an inorganic dielectric material; and
a back side of the first IC die structure comprises a backside material layer over a crystalline silicon die substrate, wherein the backside material layer is impurity-doped crystalline silicon, amorphous silicon, a compound of silicon, a compound of a metal, or a metal;
a second IC die structure of a thickness no more than 50 μm, wherein:
a back side of the IC die structure has a second region comprising one or more second metal features and an inorganic dielectric material; and
a back side of the second IC die structure further comprises a backside material layer over a crystalline die substrate and substantially coplanar with the second metal features, wherein the backside material layer comprises predominantly silicon and at least one of oxygen, nitrogen, or carbon;
a substrate in direct contact with the first region of the first IC die structure and the second region of the second IC die structure, wherein the substrate has a third region comprising one or more third metal features in contact with the first metal features and wherein the substrate has a fourth region comprising one or more fourth metal features in contact with the second metal features; and
a dielectric material over the first and second IC die structures and over a portion of the substrate beyond between the first and second IC die structures.

12. The apparatus of claim 11, wherein a front side of the second IC die structure is coupled to the second metal features by a conductive via extending through the crystalline die substrate.

13. The apparatus of claim 11, wherein the backside material layer comprises predominantly silicon and oxygen.

14. The apparatus of claim 11, wherein a plurality of recesses extends through at least a partial thickness of the backside material layer.

15. The apparatus of claim 11, wherein the backside material layer has a thickness of 100 nm-5 μm.

16. A method, comprising:
receiving a wafer of integrated circuit (IC) die structures, wherein the wafer is of a first thickness, and wherein the IC die structure has a first region comprising one or more first metal features and an inorganic dielectric material;
thinning the wafer by removing a thickness of a crystalline substrate of the IC die structures;
forming a backside material over the crystalline substrate after thinning the wafer, wherein the backside material comprises impurity-doped crystalline silicon, amorphous silicon, a compound of silicon, a compound of a metal, or a metal;
receiving a host structure with a second region comprising one or more second metal features and an inorganic dielectric material; and
bonding the first region to the second region, wherein the bonding comprises contacting the first metal features with at least a portion of corresponding ones of the second metal features.

17. The method of claim 16, further comprising aligning the IC die structure to the host structure based on a wettability contrast between the first region and the second region.

18. The method of claim 16, further comprising patterning the backside material.

19. The method of claim 16, further comprising removing the backside material from the crystalline substrate after bonding the first region to the second region.

20. The method of claim 16, wherein thinning the wafer reduces the IC die structure to a total thickness of less than 50 μm.
